(19) United States
(12) Patent Application Publication
(10) Pub. No.: US 2002/0048201 A1
(43) Pub. Date: Apr. 25, 2002

(54) First-in, first-out (FIFO) memory cell architecture

(75) Inventor: Anurag Garg, Ghaziabad (IN)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Ltd., Uttar Pradesh (IN)

(21) Appl. No.: 09/948,146

(22) Filed: Sep. 6, 2001

(30) Foreign Application Priority Data
Sep. 8, 2000 (IN) 818/DEL/2000

(51) Int. Cl. G11C 29/00

(52) U.S. Cl. 365/200

(57) ABSTRACT

A first-in, first-out (FIFO) memory cell architecture is provided in which one node of the latch in the FIFO memory cell is connected to the gate of the pass transistor. Further, the bit line is connected to the source of the pass transistor, and the word line is connected to the drain of the pass transistor to provide a stable memory cell requiring less area for implementation.

### FIELD OF THE INVENTION

The present invention relates to the field of electronic devices, and, more particularly, to a first-in, first-out (FIFO) memory cell architecture.

### BACKGROUND OF THE INVENTION

The conventional FIFO memory cell is typically a dual port memory where one of the ports is dedicated to writing and the other port is dedicated to reading. Such a prior art FIFO memory cell is illustratively shown in FIG. 1. This FIFO includes seven transistors, two word lines WWL (i.e., writing word lines) and RWL (i.e., reading word line), three bit lines (WBL, WBL(−) & RBL), and a latch which is connected to the drain of the pass transistor. The latch includes two gates each including four transistors. The bit lines WBL and WBL(−) are used for writing, and the bit line RBL (read bit line) is used to read data from the memory cell at the output.

The data (i.e., logic 0 or 1) is written through WBL and WBL(−) in the memory cell and is taken out at the source of the pass transistor when RWL is connected to the gate of pass transistor. One drawback of such a FIFO memory cell is that there may be poor stability in the memory cell during the read cycle. In addition, there may be a need to have an aspect ratio between the latch transistors and pass transistor, which limits the minimum size of the transistors.

### SUMMARY OF THE INVENTION

An object of the invention is to provide a FIFO memory cell which is stable and requires less area for implementation.

This and other objects, features, and advantages in accordance with the present invention are provided by a FIFO memory cell architecture in which one node of the latch in the FIFO memory cell may be connected to the gate of the pass transistor. Also, the bit line RBL may be connected to the source, and the word line RWL may be connected to the drain of the pass transistor to provide a substantially stable cell using less area. The size of the pass transistor may be independent of the latch transistor and may be kept to a minimum to provide further area savings.

### BRIEF DESCRIPTION OF THE DRAWINGS The invention will now be described with reference to the accompanying drawings, in which:

FIG. 1 is a schematic diagram of a conventional FIFO memory cell according to the prior art; and

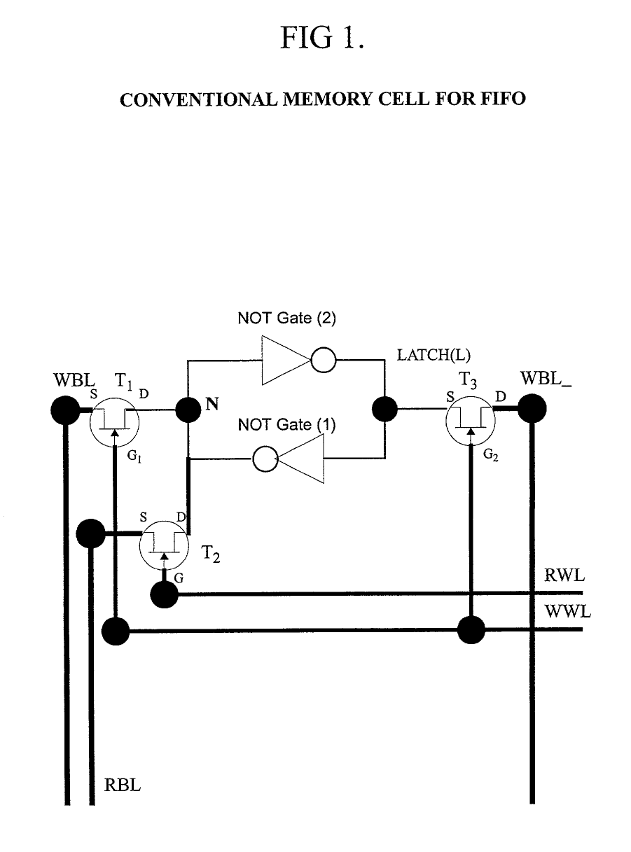

FIG. 2 is a schematic diagram of a FIFO memory cell according to the present invention.

### DETAILED DESCRIPTION OF THE PREFERRED EMBODIMENTS

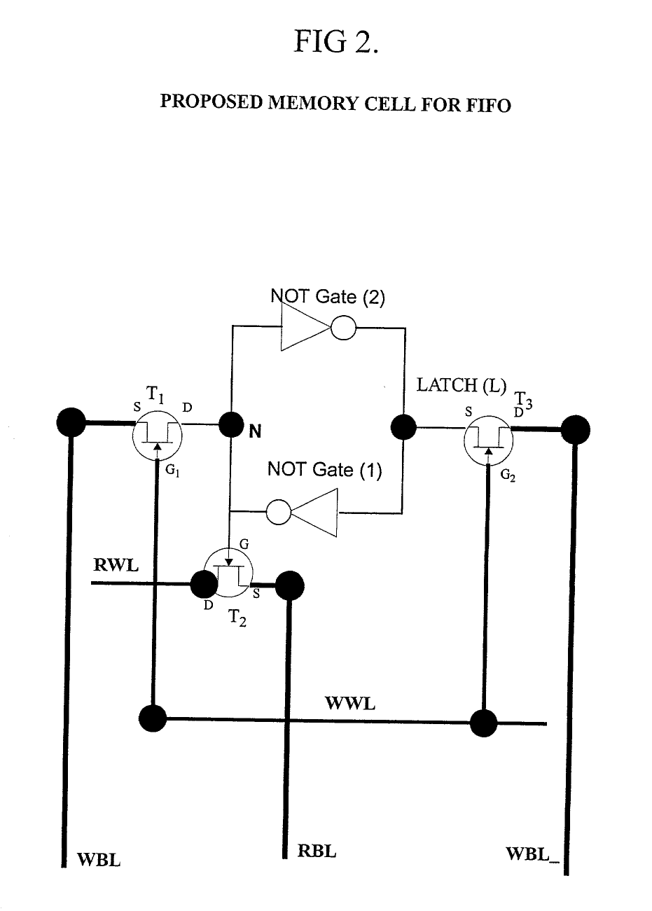

A FIFO memory cell architecture according to the present invention is illustratively shown in FIG. 2. The FIFO includes MOS transistors T1, T2 and T3. The two transistors T1 and T3 are connected to one another through a latch (L). The latch (L) includes two NOT gates (1) and (2) each including four transistors (not shown). The transistors in the latch (L) function as pull down transistors. The transistors T1 and T3 are used to perform a write operation in the memory cell, and the transistor T2 is a pass transistor. The word line WWL is connected to gates G1 and G2 of the transistors T1 and T3, respectively, and the read word line RWL is connected to the drain of transistor T2. The bit lines WBL and WBL(−) are connected to the source and drain of the transistors T1 and T3, respectively.

The bit line RBL is connected to the source of the transistors T2. The node N of the latch (L) is connected to the gate G of the transistor T2. The bit line RBL is connected to the source of the pass transistor T2, and the word line RWL is connected to the drain of the pass transistor T2. This reduces the aforementioned stability problem and the ratio requirement between the pull down transistors of the latch (L) and the pass transistor T2, and is also advantageous in terms of area savings.

During a write cycle, the word line WWL is active high, and both bit lines WBL and WBL(−) are pre-charged to VDD (power supply line). During writing operations, WWL will be selected and one of the write bit lines WBL or WBL(−) will be discharged to ground depending upon the data. Once the data has been written in the memory latch (L), both the bit lines WBL and WBL(−) are again pre-charged to VDD, and word line WWL will be deselected.

During a read cycle, RWL is normally not active and RBL is pre-charged to VDD. When the memory cell undergoes the read cycle, RWL becomes active. In such a situation, RBL will provide the bit status of the memory cell because the node N of the latch (L) is connected to the gate G of the pass transistor T2.

Stated alternatively, when data at the node of the latch (L) is at logic 1, the pass transistor T2 will be on and RBL will discharge through RWL. Thus the data at RBL will correspond to the data of the memory cell, namely logic 1. When the data at the node of the latch (L) is logic 0, the gate of the pass transistor T2 is at logic 0 and the transistor will not be on. The bit line RBL will not discharge and will be floating. This will correspond to data of the memory cell being logic 0 at RBL.

By virtue of the node N of the latch (L) being connected to the gate of the pass transistor T2, there is no ratio requirement between the transistors of the latch and the pass transistor T2. Thus, this architecture does not require a minimum transistor size, so smaller transistors may be used than in the above described prior art devices. As such, higher transistor density may be achieved to provide a more economical use of memory cell area.

In addition, since the gate of the pass transistor T2 is connected to the node of the latch (L), the architecture of the present invention does not have the above noted drawbacks of conventional memory cells which cause instability during read operations. Thus, it will be appreciated by those of skill in the art that the architecture of the present invention provides improved stability and less integration area in comparison to the prior art FIFO memory cell described above. It will also be appreciated that the present invention may advantageously be extended to any memory cell having dual ports.

That which is claimed is:

1. An improved FIFO memory cell (First in First Out mem cell) architecture characterized in that one node of the latch in the mem cell is connected to the gate of the pass transistor, bit line RBL is connected to the source and the word line RWL is connected to the drain of the pass transistor to obtain stable cell and with reduced area.

2. An improved FIFO memory cell architecture as claimed in claim 1 wherein said transistors are MOS transistors.

3. An improved FIFO memory cell architecture as claimed in claim 1 wherein the size of said pass transistor is independent of the latch transistor and can be kept minimum to save area.

4. An improved FIFO memory cell architecture substantially as herein described with reference to FIG. 2 of the accompanying drawings.
